(19) United States
(12) Patent Application Publication
(10) Pub. No.: US 2008/0211526 A1
(43) Pub. Date: Sep. 4, 2008

(54) Wafer holder, heater unit used for wafer prober and having wafer holder, and wafer prober

(76) Inventors: Kenji Shinma, Itami-shi (JP); Katsuhiro Itakura, Itami-shi (JP); Tomoyuki Awazu, Itami-shi (JP); Hirohiko Nakata, Itami-shi (JP)

Correspondence Address: MCDERMOTT WILL & EMERY LLP, 600 13TH STREET, N.W., WASHINGTON, DC, 20005-3096, US

(21) Appl. No.: 11/492,225

(22) Filed: Jul. 25, 2006

(30) Foreign Application Priority Data
Jul. 25, 2005 (JP) 2005-213832 (P)

(51) Int. Cl. G01R 31/02; B23B 5/22

(52) U.S. Cl. 324/760; 279/9.1

(57) ABSTRACT

By wafer holder including a chuck top for mounting a wafer and a supporter supporting the chuck top and having flatness of at most 0.1 mm, a heater unit for a wafer prober and the wafer prober using the wafer holder, a wafer holder and a wafer prober apparatus hardly deformable even under high load and capable of effectively preventing contact failure, and capable of preventing temperature increase in a driving system when a semiconductor wafer having semiconductor chips with minute circuitry that requires high accuracy is heated can be provided. In the wafer holder of the present invention, the flatness of the supporter is preferably at most 0.05 mm, and more preferably at most 0.01 mm.

### BACKGROUND OF THE INVENTION

1. Field of the Invention

The present invention relates to a wafer holder and a heater unit used for a wafer prober in which a semiconductor wafer is mounted on a wafer-mounting surface and a probe card is pressed onto the wafer for inspecting electric characteristics of the wafer, as well as to a wafer prober having these mounted thereon.

2. Description of the Background Art

Conventionally, in the step of inspecting a semiconductor wafer, the semiconductor wafer as an object of processing is subjected to heat treatment. Here, burn-in process is performed in which the semiconductor wafer is heated to a temperature higher than the temperature of normal use, to accelerate degradation of a possibly defective semiconductor chip and to remove the defective chip, in order to prevent defects after shipment.

In the burn-in process, before cutting the semiconductor wafer having circuits formed thereon into individual semiconductor chips, electrical characteristics of each semiconductor chip are measured and defective ones are removed while the semiconductor wafer is heated. In the burn-in process, reduction of process time is strongly desired in order to improve throughput.

In the burn-in process as such, a wafer holder containing a heater for heating the semiconductor wafer and provided with a chuck top for mounting the semiconductor wafer is used. In the conventional wafer holder, a flat metal plate has been used as the chuck top, as it is necessary to have the entire rear surface of the semiconductor wafer in contact with the ground electrode.

In the burn-in process, a semiconductor wafer having circuits formed thereon is mounted on the chuck top of the wafer holder, and electric characteristics of the semiconductor chips are measured. At the time of measurement of electric characteristics of the semiconductor chips, a probe referred to as a probe card having a number of probe pins for electric conduction is pressed onto the semiconductor wafer with a force of several tens to several hundreds kgf. Therefore, when the chuck top is thin, the chuck top might possibly be deformed, resulting in contact failure between the semiconductor wafer and a probe pin. In order to prevent such a contact failure, it is necessary to use a thick metal plate having the thickness of at least 15 mm for the chuck top, for maintaining rigidity of the chuck top and the wafer holder. When such a thick metal plate is used, however, it takes long time to increase and decrease temperature of the semiconductor wafer, which is a significant drawback in improving the throughput.

Japanese Patent Laying-Open No. 2001-033484 (Patent Document 1) proposes a wafer holder having a thin metal layer (chuck top conductive layer) formed on a ceramic substrate that is thin but of high rigidity and is not susceptible to deformation, in place of a chuck top of thick metal plate. According to Patent Document 1, as the wafer holder has high rigidity, contact failure between the semiconductor wafer and the probe pin can be avoided, and as it has small thermal capacity, temperature of the semiconductor wafer can be increased and decreased. Further, it is described that an aluminum alloy or stainless steel may be used as a support base for the wafer holder.

Recently, however, as the semiconductor processes have come to be miniaturized, the load applied per unit area of a semiconductor chip at the time of measuring electric characteristics has been increased. Consequently, it is impossible by the technique disclosed in Patent Document 1 only to sufficiently suppress deformation of the wafer holder at the time of measuring electric characteristics of the semiconductor chip, and it is impossible to fully prevent contact failures.

Further, recently, as the semiconductor processes have come to be miniaturized, high accuracy comes to be required at the time of registering the probe card and the wafer holder. A wafer holder typically repeats operations of heating a semiconductor wafer to a prescribed temperature, moving to a prescribed position at the time of measuring electric characteristics, and pressing a probe card to the semiconductor wafer. At this time, in order to move the wafer holder to the prescribed position, driving system thereof is also required of high accuracy.

There is a problem, however, that when the semiconductor wafer is heated to a prescribed temperature, for example, to 100 to 200° C., the heat is transferred to the driving system, and metal members forming the driving system thermally expands, degrading accuracy of the driving system. This is also a cause of a contact failure during an inspection of a semiconductor chip particularly having a minute circuitry.

### SUMMARY OF THE INVENTION

The present invention was made to solve the above-described problems, and its object is to provide a wafer holder hardly deformable even under high load and capable of effectively preventing contact failure, and capable of preventing temperature increase in a driving system when a semiconductor wafer having semiconductor chips with minute circuitry that requires high accuracy is heated, as well as a heater unit for a wafer using the same and the wafer prober.

The wafer holder in accordance with the present invention is characterized in that it includes a chuck top for mounting a wafer, and a supporter supporting the chuck top and having flatness of at most 0.1 mm.

According to the present invention, in the wafer holder including a chuck top mounting and fixing a wafer and a supporter supporting said chuck top, the flatness of said supporter is set to at most 0.1 mm, and therefore, a wafer holder hardly deformable under high load and capable of effectively preventing contact failure can be provided.

In the wafer holder in accordance with the present invention, the flatness of the supporter is preferably at most 0.05 mm and, more preferably, at most 0.01 mm.

Further, Young's modulus of said supporter is preferably at least 200 GPa, and the shape of the supporter preferably has a circular tube portion or a plurality of pillars.

Further, thermal conductivity of the supporter is preferably at most 40 W/mK, and specific material is, preferably, any of mullite, alumina, and a mullite-alumina composite.

Further, the present invention also provides a heater unit for a wafer prober including the wafer holder of the present invention described above, and a wafer prober mounting the heater unit.

The heater unit for a wafer prober including the wafer holder and the wafer prober including the heater unit as such have high rigidity, and as the heat insulating effect is enhanced, positional accuracy can be improved, thermal uniformity can be improved, and further, rapid heating and cooling of the chip can be realized.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view schematically showing a wafer holder 1 as a first preferred example of the present invention.

FIG. 2 is a cross-sectional view schematically showing a wafer holder 11 as a second preferred example of the present invention.

FIG. 3 is a top view schematically showing a supporter 12 of FIG. 2.

FIG. 4 is a cross-sectional view schematically showing a wafer holder 21 as a third preferred example of the present invention.

FIG. 5 is a top view schematically showing a supporter 22 of FIG. 4.

FIG. 6 is a cross-sectional view schematically showing a wafer holder 31 as a fourth preferred example of the present invention.

FIG. 7 is a cross-sectional view schematically showing a wafer holder 36 as a fifth preferred example of the present invention.

FIG. 8 shows, partially in enlargement, a heater body 32 shown in FIG. 6.

FIG. 9 shows, partially in enlargement, a contact portion between a chuck top 2 and a circular tube portion 14 of wafer holder 36 of the example shown in FIG. 7.

FIG. 10 is a cross-sectional view schematically showing a wafer holder 51 as a sixth preferred example of the present invention.

FIG. 11 is a top view schematically showing a supporter 52 of FIG. 10.

FIG. 12 is a top view schematically showing a supporter 61 suitably used for a wafer holder of the present invention.

FIG. 13 is a top view schematically showing a supporter 66 suitably used for a wafer holder of the present invention.

FIG. 14 is a cross-sectional view schematically showing a wafer holder 71 as a seventh preferred example of the present invention.

FIG. 15 is a cross-sectional view schematically showing a wafer holder 76 as an eighth preferred example of the present invention.

FIG. 16 is a cross-sectional view schematically showing a wafer holder 81 as a ninth preferred example of the present invention.

### DESCRIPTION OF THE PREFERRED EMBODIMENTS

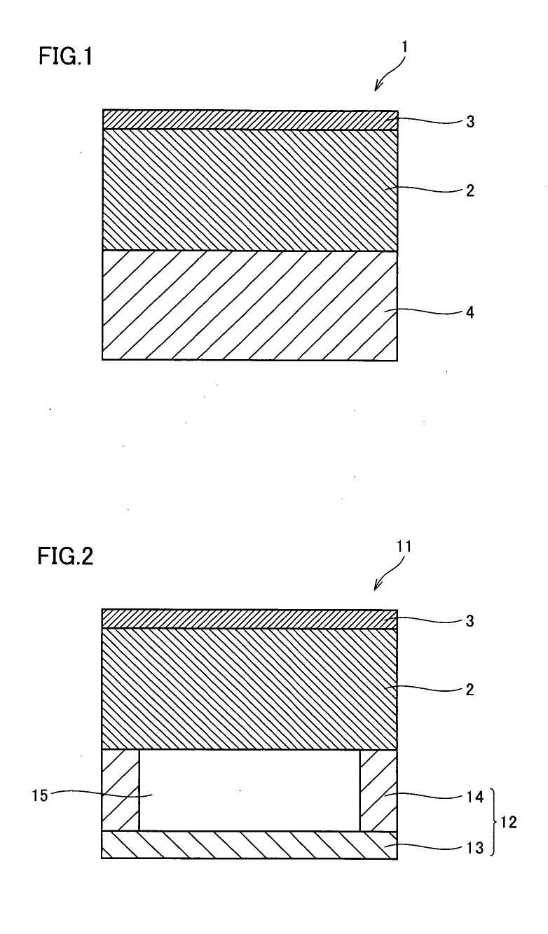

FIG. 1 is a cross-sectional view schematically showing a wafer holder 1 as a first preferred example of the present invention. As shown in FIG. 1, wafer holder 1 in accordance with the present invention basically includes a chuck top 2 for mounting a wafer, and a supporter 4 supporting chuck top 2. Typically, on chuck top 2, a chuck top conductive layer 3 such as shown in FIG. 1 is formed. Further, supporter 4 is mounted on a driving system (not shown) for moving the wafer holder as a whole.

Wafer holder 1 of the present invention is characterized in that flatness of supporter 4 is at most 0.1 mm. As the flatness of supporter 4 is made at most 0.1 mm, even when it is impossible to support the load of probe card only by the rigidity of the chuck top itself, the load acting on chuck top 2 can effectively be supported by supporter 4, and as a result, deformation of chuck top 2 can be prevented. It is preferable that the flatness of supporter 4 is made 0.05 mm or smaller, as the amount of deformation can further be reduced. Ideally, the flatness of supporter 4 should be made 0.01 mm or smaller, as the amount of deformation can extremely be made small.

Here, flatness of supporter 4 refers to the flatness of a supporter surface supporting the chuck top, and it may be measured using, for example, a three-dimensional measuring apparatus.

Further, in wafer holder 1 in accordance with the present invention, supporter 4 preferably has Young's modulus of at least 200 GPa. When supporter 4 has Young's modulus of at least 200 GPa, deformation of supporter 4 itself can be made small, and hence, deformation of the chuck top can further be suppressed. From the viewpoint that deformation of the supporter can also be significantly reduced and hence the supporter can be reduced in size and weight, Young's modulus of supporter 4 is more preferably at least 300 GPa.

Here, Young's modulus of supporter 4 refers to a value measured by a method such as pulse method or flexural resonance method.

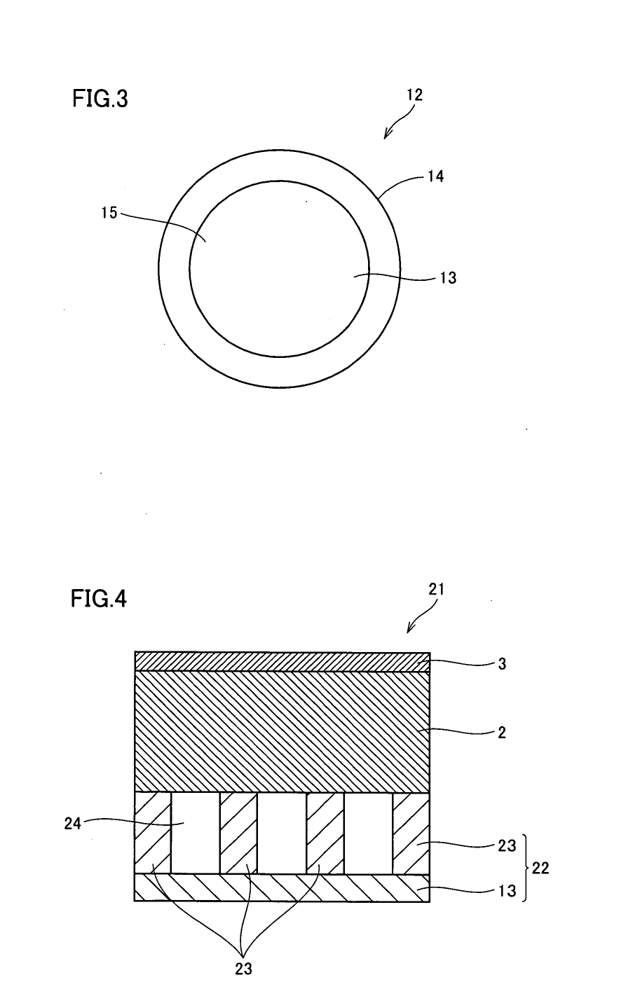

In wafer holder 1 of the present invention, the shape of supporter 4 is not specifically limited. FIG. 1 shows, as an example, supporter 4 formed as a solid cylinder. FIG. 2 is a cross-sectional view schematically showing a wafer holder 11 as a second preferred example of the present invention, and FIG. 3 is a top view schematically showing a supporter 12 of FIG. 2. In the example shown in FIG. 2, portions having similar structures as wafer holder 1 of the example shown in FIG. 1 are denoted by the same reference characters and description thereof will not be repeated. In wafer holder 11 of the example shown in FIG. 2, supporter 12 is formed of a supporter bottom portion 13 and a circular tube portion 14 formed thereon.

FIG. 4 is a cross-sectional view schematically showing a wafer holder 21 as a third preferred example of the present invention and FIG. 5 is a top view of a supporter 22 of FIG. 4. In the example shown in FIG. 4, portions having similar structures as wafer holders 1 and 11 of the examples shown in FIGS. 1 and 3 are denoted by the same reference characters and description thereof will not be repeated. In wafer holder 21 of the example shown in FIG. 4, supporter 22 is formed of a supporter bottom portion 13 and a plurality of pillars 23 formed thereon.

In the wafer holder of the present invention, it is preferred that the supporter is formed to include a circular tube portion (such as a structure shown in FIG. 2 or 3) or a plurality of pillars (such as a structure shown in FIG. 4 or 5). When the circular tube portion or pillars are provided, it follows that most of the volume of the supporter would be occupied by space 15 or 24, and therefore, the heat transfer path from chuck top 2 through supporter 12, 22 to the driving system (not shown) of wafer holder 11, 21 becomes thinner. Therefore, temperature increase in the driving system can be prevented, while rigidity of supporters 12, 22 can be maintained and there is no adverse influence on the effect of suppressing deformation of chuck top 2.

As in the example shown in FIG. 2, when wafer holder 11 is realized using supporter 12 provided with circular tube portion 14, it is preferred that the thickness of circular tube portion 14 is at most 20 mm. When the thickness of circular tube portion 14 exceeds 20 mm, the amount of heat transferred from chuck top 2 through supporter 11 to the driving system of wafer holder 11 tends to increase. Further, the thickness of circular tube portion is preferably at least 1 mm. When the thickness of circular tube portion 14 becomes smaller than 1 mm, supporter 12 itself may possibly be deformed or damaged by the load of probe card.

When supporter 12 includes circular tube portion 14, the height of circular tube portion 14 should preferably be at least 10 mm. When the height of circular tube portion 14 is smaller than 10 mm, the amount of heat transferred from chuck top 2 through supporter 12 to the driving system of wafer holder 11 tends to increase.

When supporter 22 is implemented with a plurality of pillars 23 as in the example shown in FIG. 4, it is preferred that pillars 23 are in uniform, concentrical arrangement or in a similar arrangement, and that the number is at least 8. Recently, wafer size has come to be increased to 8 to 12 inches, and therefore, if the number is smaller, distance between pillars would be long, and the function of supporting the chuck top when the load is applied by the probe card would be deteriorated, possibly leading to deformation of the chuck top. The shape of the pillar may be a cylinder, or it may be a triangle pole, a quadrangular pole, a pipe or may have any other polygonal shape, and its cross sectional area is not specifically limited.

When it is provided with a bottom portion 13 as in the examples shown in FIGS. 2 and 4, thickness of bottom portion 13 of the supporter is preferably at least 10 mm. When the thickness of bottom portion 13 of the supporter is smaller than 10 mm, the supporter itself might possibly be deformed or damaged by the load of the probe card. Further, bottom portion 13 of the supporter and circular tube portion 14 or pillars 23 may be formed integrally or formed as separate bodies. When these are formed as separate bodies, there is formed an interface between the bottom portion 13 of the supporter and circular tube portion 14 or pillars 23, and it is preferred as the interface serves as a heat resistance and the amount of heat transferred from chuck top 2 through supporter 12, 22 to the driving system of the wafer holder is reduced.

The supporter of wafer holder 1 in accordance with the present invention preferably has thermal conductivity of at most 40 W/mK. When the thermal conductivity of the supporter is set to at most 40 W/mK, the amount of heat transferred from the chuck top through the supporter to the driving system of the wafer holder can further be reduced, and temperature increase of the driving system can effectively be prevented. Recently, a temperature as high as 150° C. is required at the time of probing, and therefore, it is particularly preferred that the supporter has thermal conductivity of at most 10 W/mK. More preferable thermal conductivity is at most 5 W/mK. With the thermal conductivity of this range, amount of heat transfer from the supporter to the driving system decreases significantly.

Here, the thermal conductivity of the supporter refers to a value measured by a method such as laser flash method, using palletized samples.

As the material allowing processing to a supporter having the above-described flatness and shape and having, as physical properties, such Young's modulus and thermal conductivity as described above, mullite, alumina or a mullite-alumina composite material is preferred, considering processability and cost.

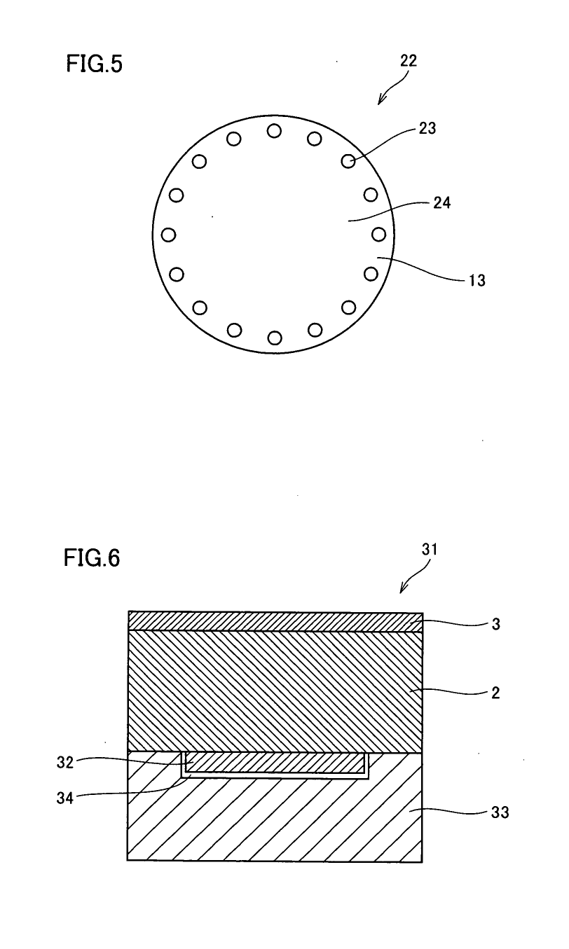

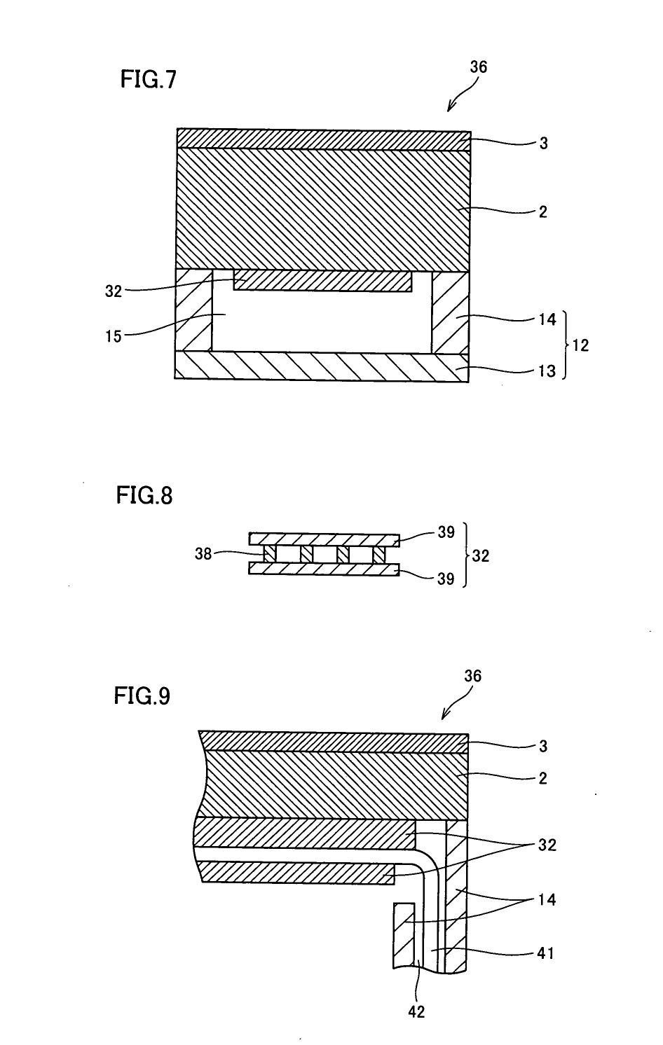

FIG. 6 is a cross-sectional view schematically showing a wafer holder 31 as a fourth preferred example of the present invention, and FIG. 7 is a cross-sectional view schematically showing a wafer holder 36 as a fifth preferred example of the present invention. In the examples shown in FIGS. 6 and 7, portions having the same structure as wafer holders 1 and 11 shown in FIGS. 1 and 2 will be denoted by the same reference characters and description thereof will not be repeated.

Wafer-holders 31 and 36 shown in the examples of FIGS. 6 and 7 each have chuck top 2 with a heater body 32. In the step of inspecting a semiconductor, heating of a wafer may or may not be required. Recently, however, it is more often the case that heating to 100 to 200° C. is required, and thus, wafer holders 31 and 36 including a heater body as shown in FIGS. 6 and 7 are preferably provided.

The example shown in FIG. 6 includes a supporter 33 having a solid cylindrical shape similar to the example shown in FIG. 1, with a recessed portion formed at an upper portion where chuck top 2 is provided. Heater body 32 is attached to a lower portion of chuck top 2, and housed with a space 34 in said recessed portion of supporter 33. Further, in the example shown in FIG. 7, heater body 32 is attached to a lower portion of chuck top 2, and housed in a space 15 in circular tube portion 14 of supporter 12.

Here, FIG. 8 shows, partially in enlargement, a heater body 32 shown in FIG. 6. As heater body 32 used in the present invention, one having a simple structure having a resistance heater body 38 sandwiched between insulators 39 as shown in FIG. 8 may preferably be used.

As resistance heater body 38, metal material may be used. By way of example, foil formed of nickel, stainless steel, silver, tungsten, molybdenum, chromium, nichrome and an alloy of these metals may preferably be used. Among these, a resistance heater body formed of stainless steel or nichrome is preferably used. Stainless steel or nichrome allows formation of a circuit pattern of resistance heater body with relatively high precision by a method such as etching, when it is processed to the shape of the heater body. Further, it is preferred because it is inexpensive, and is oxidation resistant and withstands use for a long period of time even when the temperature of use is high.

Insulator 39 sandwiching resistance heater body 38 is not specifically limited, and any heat-resistant insulator may be used. By way of example, mica, silicone resin, epoxy resin, phenol resin or the like may be used. When insulator 39 is resin, filler may be dispersed in the resin, in order to increase thermal conductivity of insulator 39. Filler material is not specifically limited, provided that it does not have reactivity to the resin, and a substance such as boron nitride, aluminum nitride, alumina, silica or the like may be available.

Heater body 32 may be fixed on chuck top 2 by a mechanical method, for example, by fixing with a screw. Alternatively, heater body 32 may be provided by forming an insulating layer by thermal spraying or screen printing on a surface opposite to the wafer-mounting surface of chuck top 2, and forming a conductive layer in a prescribed pattern thereon by screen printing or vapor deposition.

When chuck top 2 is heated by heater body 32 and inspection is performed, for example, at 200° C., it is preferred that the temperature at a bottom surface of the supporter is at most 100° C. When the temperature at the bottom surface of the supporter exceeds 100° C., there would be a contact failure caused by thermal expansion of the driving system of the wafer holder. Further, when the temperature at the bottom surface of the supporter exceeds 100° C. and the measurement is to be done at a room temperature after the inspection at 200° C., cooling takes time and hence, throughput would be decreased.

FIG. 9 shows, partially in enlargement, a contact portion between a chuck top 2 and a circular tube portion 14 of wafer holder 36 of the example shown in FIG. 7. As shown in FIG. 9, at circular tube portion 14 of supporter 12, a through hole 42 is preferably formed for inserting an electrode line 41 for feeding power to heater body 32 or an electrode line (not shown) for electromagnetic shield. Such a structure advantageously facilitates handling of electrode line 41. Here, the position for forming through hole 42 is preferably close to an inner circumferential surface of the circular tube portion 14, as decrease in strength at the circular tube portion 14 can be minimized.

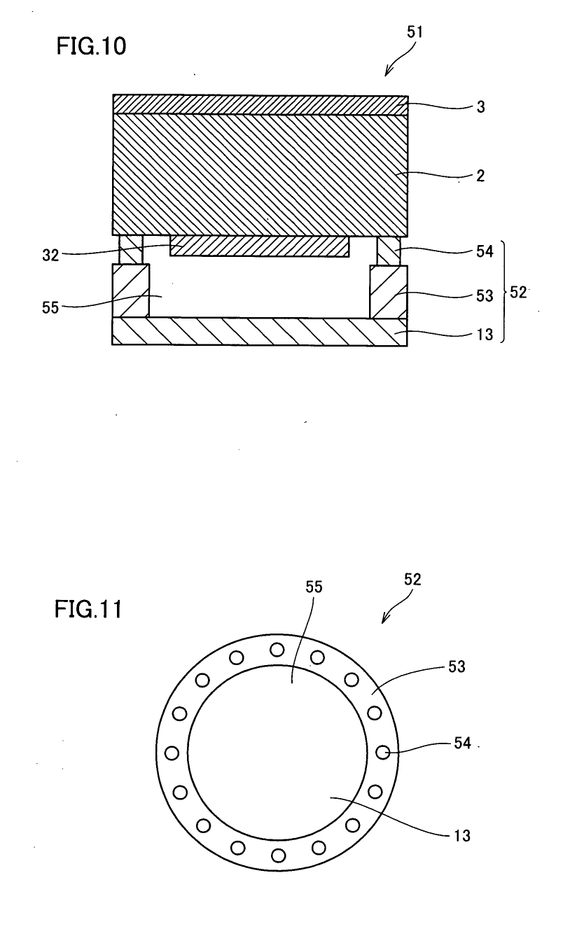

FIG. 10 is a cross-sectional view schematically showing a wafer holder 51 as a sixth preferred example of the present invention. FIG. 11 is a top view schematically showing a supporter 52 of FIG. 10. In wafer holder 51 of the example shown in FIG. 10, portions of the same structure as wafer holders 11, 21 and 36 of the examples of FIGS. 2, 4 and 7, respectively, are denoted by the same reference characters and description thereof will not be repeated. Wafer holder 51 of the present invention may be implemented to include a supporter 52 having both a circular tube portion 53 and a plurality of pillars 54, as shown in FIGS. 10 and 11. In the example shown in FIG. 10, circular tube portion 53 is provided on bottom portion 13 of the supporter, the plurality of pillars 54 are provided on circular tube portion 53, and chuck top 2 with heater body 32 attached is provided thereon. Use of circular tube portion 53 and the plurality of pillars 54 in combination is preferred, as the amount of heat transferred to the driving system of the wafer holder can be reduced by the space 55 of pillars 54 and circular tube portion 53, without increasing deformation of supporter 52 and chuck top 2.

In the wafer holder in accordance with the present invention, surface roughness Ra at a contact portion between the supporter arid the chuck top is, both at the supporter and at the chuck top, preferably at least 0.1 μm. By setting said surface roughness Ra to be at least 0.1 μm, thermal resistance at the contact surface between the supporter and the chuck top increases, and therefore, the amount of heat transferred to the driving system of the wafer holder can be reduced. There is no specific upper limit for the surface roughness Ra. As for the method of realizing surface roughness Ra of at least 0.1 μm, polishing process or sand blasting may be performed.

In addition to the contact portion between the supporter and the chuck top, it is preferred to have the surface roughness Ra of at most 0.1 μm at the contact surface between the bottom surface of the supporter and the driving system, the contact surface between the bottom portion of the supporter and the circular tube portion or the pillar when the bottom portion of the supporter and the circular tube portion or the pillar are formed as separate bodies, and at the contact portion between the circular tube portion and the plurality of pillars when the circular tube portion and the plurality of pillars are used in combination, because the thermal resistance increases and the amount of heat transferred to the driving system of the wafer holder can be reduced. Reduction in heat quantity transferred to the driving system, attained by the increased thermal resistance, eventually leads to reduction of power supply to the heater body.

Further, in the wafer holder of the present invention, it is preferred that a metal layer is formed on a surface of the supporter. Electric field or electromagnetic wave generated from the heater body heating the chuck top, driving portion of the prober or peripheral devices may affect wafer inspection as noise, and formation of the metal layer on the supporter is preferred as the electromagnetic wave can be intercepted (shielded). The method of forming the metal layer is not specifically limited. By way of example, a conductive paste prepared by adding glass frit to metal powder of silver, gold, nickel or copper may be applied using a brush and burned.

When the metal layer is formed on the surface of the supporter, metal such as aluminum or nickel may be formed by thermal spraying. Alternatively, the metal layer may be formed by plating on the surface of the supporter. Further, such methods may arbitrarily be combined. Specifically, after the conductive paste is burned, metal plating of nickel or the like may be provided, or plating may be formed after thermal spraying. Among these methods, plating is preferred, as it has high contact strength and is highly reliable. Further, thermal spraying is preferred as it allows formation of the metal film at a relatively low cost.

In the wafer holder of the present invention, it is also possible to attach a conductor of a circular tube shape on a side surface of the supporter. The material used here is not specifically limited, as long as it is a conductor. By way of example, metal foil or a metal plate of stainless steel, nickel, aluminum or the like may be formed to have a circular tube shape of a size larger than the outer diameter of the supporter, and attached to the side surface of the supporter. Further, at the bottom surface portion of the supporter, metal foil or a metal plate may be attached, and by connecting this to the metal foil or metal plate attached to the side surface, the effect of shielding the electromagnetic wave can be enhanced.

When the supporter has a space inside as shown in the examples of FIGS. 2 and 4, the metal foil or metal plate may be attached utilizing the space, and by connecting this to the metal foil or metal plate attached to the side surface and the bottom surface, the effect of shielding the electromagnetic wave can be enhanced. Adoption of such a method is preferred as the electromagnetic wave can be shielded at a lower cost than when plating or conductor paste is applied. Though the method of fixing the metal foil and the metal plate to the support body is not specifically limited, the metal foil and the metal plate may be attached to the supporter using, for example, metal screws. Further, the metal foil or the metal plates on the bottom surface portion and on the side surface portion may be integrated beforehand and then fixed on the supporter.

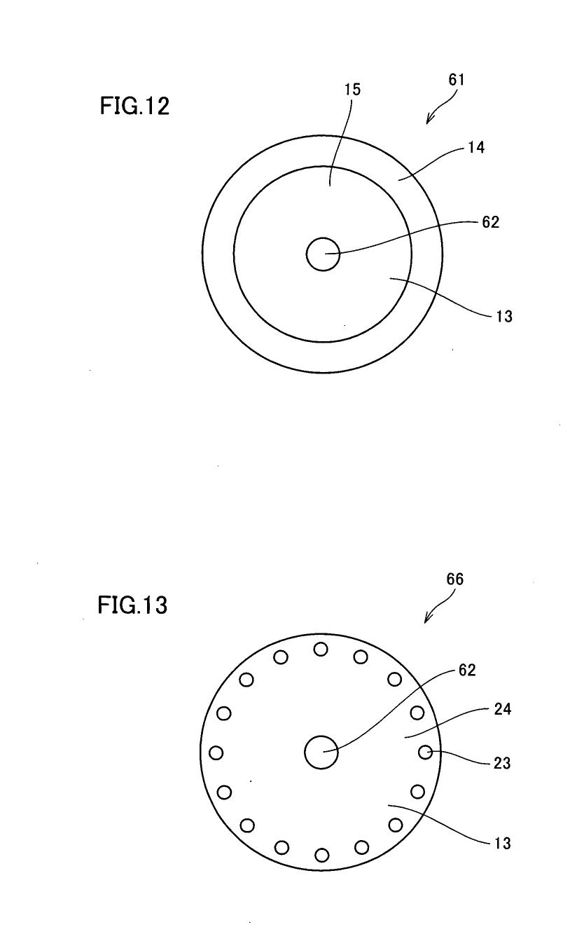

FIGS. 12 and 13 are top views schematically showing supporters 61 and 66 suitably used in the wafer holder of the present invention. Supporters 61 and 66 shown in FIGS. 12 and 13 have the same structures as supporters 12 and 22 shown FIGS. 3 and 5, respectively, except that a support rod 62 is provided, and portions having the same structure are denoted by the same reference characters and description thereof will not be repeated. When the supporter used in the present invention includes circular tube portion 14 or plurality of pillars 23, it is preferred that the supporter is provided with support rod 62 near the center, as shown in FIGS. 12 and 13.

By the provision of support rod 62, deformation of the chuck top when the load is applied by the probe card can further be suppressed. Preferably, the material of support rod 62 is the same as the material of circular tube portion 14 or pillar 23. When circular tube portion 14 or pillar 23 and support rod 62 thermally expand because of the heat from the heater body and the materials are different, a step would possibly be generated between the circular tube portion or the pillar and the support rod, because of a difference in thermal expansion coefficient.

As to the size of support rod 62, it is preferred that cross-sectional area is at least 0.1 cm². When the cross-sectional area is smaller, the supporting effect would be insufficient, and support rod 62 tends to deform. The cross-sectional area should preferably be at most 100 cm². When the cross-sectional area is larger than this, the amount of heat transferred to the driving system would possibly increase. The shape of support rod 62 is not specifically limited and it may be a cylinder (FIGS. 12, 13), or it may be a triangle pole, a quadrangular pole, a pipe or the like.

As to the method of fixing support rod 62 to the supporter, methods such as brazing with an active metal, glass fixing, or screw fixing may be used, and among these methods, screw fixing is particularly preferred. Screw fixing facilitates attachment/detachment, and as heat treatment is not involved at the time of fixing, deformation of the supporter or the support rod by the heat treatment can be avoided.

Further, in the wafer holder of the present invention, it is preferred that an electromagnetic shield layer for shielding the electromagnetic wave is formed between the heater body heating the chuck top and the chuck top. For forming the electromagnetic shield layer, said method of forming a metal layer on the supporter surface may be used and, by way of example, it may be formed by inserting metal foil between the heater body and the chuck top. The material of metal foil used for forming the electromagnetic shield is not specifically limited, and stainless steel, nickel, aluminum or the like may be used.

Preferably, the wafer holder of the present invention further includes an insulating layer between said electromagnetic shield layer and the chuck top. The insulating layer serves to shield the noise such as the electromagnetic wave or electric field generated at the heater body and the like that may affect inspection of the wafer. The noise particularly has significant influence on measurement of high-frequency characteristics of the wafer, and the noise does not have much influence on the measurement of normal electric characteristics. Specifically, though most of the noise generated at the heater body is shielded by said electromagnetic shield layer, in terms of electric circuit, a capacitor is formed between the chuck top conductive layer formed on the wafer-mounting surface of the chuck top and the electromagnetic shield layer when the chuck top is an insulator, or between the chuck top itself and the heater body when the chuck top is a conductor, and the capacitor may have an influence as a noise at the time of inspecting the wafer. In order to reduce the influence, an insulating layer may be formed between the electromagnetic shield layer and the chuck top.

Further, it is preferred that the wafer holder in accordance with the present invention includes a guard electrode layer between the chuck top and the electromagnetic shield electrode layer, with an insulating layer interposed. When connected to the metal member formed on said supporter, the guard electrode layer can further reduce the noise that affects measurement of the high-frequency characteristics of the wafer. Specifically, in the present invention, by covering the supporter as a whole including the heater body with a conductor, the influence of noise at the time of measuring the characteristics of the wafer at a high frequency can be reduced. Further, by connecting the guard electrode layer to the metal member provided on said supporter, the influence of noise can further be reduced.

Here, it is preferred that the resistance value of said insulating layer is at least 10⁷Ω. When said resistance value is smaller than 10⁷Ω, small current flows to the chuck top conductive layer because of the influence of heater body, which possibly becomes noise at the time of probing and affects probing. Setting the resistance value of the insulating layer to be at least 10⁷Ω is preferable as the small current can sufficiently be reduced not to affect proving. Recently, circuit patterns formed on semiconductor wafers have been miniaturized, and therefore, it is necessary to reduce such noise as much as possible. By setting the resistance value of the insulating layer to at least 10¹⁰Ω, higher reliability can be attained.

Further, it is preferred that the dielectric constant of said insulating layer is at most 10. When the dielectric constant of the insulating layer exceeds 10, charges tend to be stored more easily at the electromagnetic shield layer sandwiching the insulating layer, the guard electrode layer and the chuck top, which might possibly be a cause of noise generation. Particularly, as the wafer circuits have been much miniaturized in these days as described above, it is necessary to reduce noise, and therefore, dielectric constant should preferably be at most 4 and more preferably at most 2. By setting small the dielectric constant, the thickness of the insulating layer necessary for ensuring insulation resistance and capacitance can be made thinner, and hence, thermal resistance posed by the insulating layer can be reduced.

Further, when the chuck top is an insulator, capacitance between the chuck top conductive layer and the guard electrode layer, and between the chuck top conductive layer and the electromagnetic shield electrode layer, or when the chuck top is a conductor, the capacitance between the chuck top itself and the guard electrode, and between the chuck top itself and the electromagnetic shield electrode layer, should preferably be at most 5000 pF. When the capacitance exceeds 5000 pF, the influence of the insulating layer as a capacitor would be too large, possibly becoming noise at the time of probing. Capacitance of at most 1000 pF between the chuck top itself and the guard electrode layer and between the chuck top itself and the electromagnetic shield layer is particularly preferred, as it enables inspection free of noise influence of even a miniaturized circuitry.

As described above, in the wafer holder of the present invention, the insulating layer as described above is formed, and the resistance value, dielectric constant and capacitance of the insulating layer are controlled within the above-described ranges, whereby the noise at the time of inspection can significantly be reduced.

The thickness of the insulating layer should preferably be at least 0.2 mm. In order to reduce the size of the device and to maintain good heat conduction from the heater body to the chuck top, the thickness of the insulating layer should be small. When the thickness of the insulating layer becomes smaller than 0.2 mm, however, defects in the insulating layer itself or problems in durability would be generated. It is preferred that the insulating layer used in the present invention has the thickness of at least 1 mm, because such a thickness prevents the problem of durability and ensures good heat conduction from the heater body.

The thickness of the insulating layer used in the present invention is preferably at most 10 mm. When the thickness of the insulating layer exceeds 10 mm, though the noise cutting effect is good, the time of conduction of the heat generated by heater body to the chuck top and to the wafer becomes too long, and hence, it becomes difficult to control the heating temperature. Though it depends on the conditions of inspection, the thickness of the insulating layer up to 5 mm is preferred, as temperature control is relatively easy.

The thermal conductivity of the insulating layer is preferably at least 0.5 W/mK, in order to realize good heat conduction from the heater body as described above. Thermal conductivity of the insulating layer of at least 1 W/mK is preferred, as heat conduction is further improved. The thermal conductivity of the insulating layer may be measured by the similar method as described with reference to the thermal conductivity of the supporter above.

Specific material for the insulating layer has only to satisfy the characteristics described above and have heat resistance sufficient to withstand the inspection temperature, and possible example may be ceramics or resin. Of these, resin such as silicone resin or the resin having filler dispersed therein, and ceramics such as alumina, may preferably be used. The filler dispersed in the resin serves to improve heat conduction of the resin, and any material having no reactivity to the resin may be used, and by way of example, substances such as boron nitride, aluminum nitride, alumina and silica may be available.

The size of the area on which the insulating layer is formed is preferably the same or larger than the size of the areas for forming said electromagnetic shield electrode layer, the guard electrode and the heater body. If the area for forming is smaller, noise may possibly enter from a portion not covered with the insulating layer.

An example of the insulating layer will be described in the following. First, as the material, silicone resin having boron nitride dispersed therein is used. The material has thermal conductivity of about 5 W/mK, and dielectric constant of 2. When the silicone resin with boron nitride dispersed is inserted as the insulating layer between said electromagnetic shield layer and the chuck top, and the chuck top corresponds to a 12-inch wafer, it may be formed, for example, to have the diameter of 300 mm. At this time, when the thickness of the insulating layer is set to 0.25 mm, capacitance of 5000 pF can be attained. When the thickness is set to 1.25 or more, capacitance of 1000 pF or lower can be attained. Volume resistivity of the material is 9×10¹⁵ Ω·cm, and therefore, when the diameter is 300 mm and the thickness is made at least 0.8 mm, the resistance value of about 1×10¹²Ω can be attained. Therefore, when the thickness is made at least 1.25 mm, an insulating layer having sufficiently low capacitance and sufficiently high resistance value can be obtained.

In the wafer holder of the present invention, when the chuck top warps by more than 30 μm, contact with a needle of the probe card may possibly be biased at the time of inspection, resulting in a contact failure. Similar contact failure would be possible if the parallelism between the surface of the chuck top conductive layer and the bottom surface of the supporter is 30 μm or larger. Said warp and parallelism should be smaller than 30 μm not only at a room temperature but also in the general temperature range of inspection of −70° C. to 200° C.

The chuck top conductive layer formed on the wafer-mounting surface of the chuck top has a function of a ground electrode and, in addition, functions of cutting off electromagnetic noise from the heater body, and protecting the chuck top from corrosive gas, acid, alkali chemical, organic solvent or water.

Possible methods of forming the chuck top conductive layer include a method in which a conductive paste is applied by screen printing and then fired, vapor deposition or sputtering, thermal spraying and plating. Among these methods, thermal spraying and plating are particularly preferred. These methods do not involve heat treatment at the time of forming the conductive layer, and therefore, warp of the chuck top caused by heat treatment can be avoided and the conductive layer can be formed at a low cost.

Particularly, a method of forming the chuck top conductive layer by forming a thermally sprayed film on the chuck top and then forming a plating film further thereon is preferred. The material thermally sprayed (aluminum, nickel or the like) forms some oxide, nitride or oxynitride at the time of thermal spraying, and such compound reacts to the chuck top surface, realizing firm contact. The thermally sprayed film, however, has low electric conductivity because it contains the compound mentioned above. In contrast, plating forms an almost pure metal film, and therefore, a conductive layer of superior electric conductivity can be formed. Contact strength with the chuck top surface, however, is not as high as that of the thermally sprayed film. The thermally sprayed film and the plating film both contain metal as the main component and, therefore, contact strength therebetween is high. Therefore, by forming the thermally sprayed film as a base and forming plating film thereon, a chuck top conductive layer having both high contact strength and high electric conductivity can be provided.

In the wafer holder of the present invention, the chuck top conductive layer preferably has the surface roughness Ra of at most 0.5 μm. When the surface roughness Ra of the chuck top conductive layer exceeds 0.5 μm, the heat generated from a device having a high calorific value during inspection of the device could not be radiated from the chuck top, and the device might possibly be broken by the heat. The surface roughness Ra of said chuck top conductive layer should more preferably be at most 0.02 μm, as more efficient heat radiation becomes possible.

In the wafer holder of the present invention, it is preferred that the thickness of the chuck top is at least 8 mm. When the thickness of the chuck top is smaller than 8 mm, the chuck top deforms significantly when load is applied at the time of inspection, causing contact failure and possibly a damage to the wafer. The thickness of the chuck top is more preferably be at least 10 mm, as the possibility of contact failure can be reduced.

Further, in the wafer holder of the present invention, Young's modulus of the chuck top should preferably be at least 250 GPa. If Young's modulus is smaller than 250 GPa, the chuck top would be significantly deformed when load is applied at the time of inspection, resulting in a contact failure and possibly causing damage to the wafer. Young's modulus of the chuck top should preferably be at least 250 GPa and more preferably at least 300 GPa, as the possibility of contact failure can further be reduced. Young's modulus of the chuck top can be measured by the similar method as that of measuring Young's modulus of the supporter described above.

In the wafer holder of the present invention, the chuck top preferably has thermal conductivity of at least 15 W/mK. When the thermal conductivity of the chuck top is lower than 15 W/mK, temperature uniformity of the wafer mounted on the chuck top would be deteriorated. When the thermal conductivity of the chuck top is not lower than 15 W/mK, thermal uniformity having no adverse influence on inspection can be attained. Chuck top of 170 W/mK or higher is more preferable, as the thermal uniformity of the wafer can further be improved. Thermal conductivity of said chuck top can be measured by the similar method as that of measuring thermal conductivity of the supporter described above.

As the material for the chuck top having such Young's modulus and thermal conductivity as described above, various ceramics and metal-ceramics composite materials may be available. Preferred metal-ceramics composite material is either composite material of aluminum and silicon carbide (Al—SiC) or composite material of silicon and silicon carbide (Si—SiC), which has relatively high thermal conductivity and easily realizes thermal uniformity when the wafer is heated. Of these, Si—SiC is particularly preferred, as it has high thermal conductivity of 170 W/mK to 220 W/mK and high Young's modulus.

Further, as these composite materials are conductive, they may be used as materials for the heater body. By way of example, the heater body may be formed by forming an insulating layer through a method of thermal spraying or screen printing on a surface opposite to the wafer-mounting surface of the chuck top, and by screen printing the conductive layer thereon using the composite material mentioned above, or by forming the conductive layer in a prescribed shape through a method such as vapor deposition.

Alternatively, metal foil of stainless steel, nickel, silver, molybdenum, tungsten, chromium and an alloy of these may be etched to form a prescribed pattern, to provide the heater body. In this method, insulation from the chuck top may be attained by the method similar to that described above, or an insulating sheet may be inserted between the chuck top and the heater body. This is preferable, as the insulating layer can be formed at considerably lower cost and in a simpler manner than the method described above. Resin available for this purpose includes, from the viewpoint of heat resistance, mica sheet, epoxy resin, polyimide resin, phenol resin and silicone resin. Among these, mica is particularly preferable, as it has superior heat resistance and electric insulation, allows easy processing and is inexpensive.

Use of ceramics as the material for the chuck top is advantageous in that formation of an insulating layer between the chuck top and the heater body is unnecessary. Among ceramics, alumina, aluminum nitride, silicon nitride, mullite, and a composite material of alumina and mullite are preferred as they have relatively high Young's modulus and hence, not much deformed by the load of the probe card. Of these, alumina is preferred as it can be used at a relatively low cost and it has high insulation characteristic at a high temperature. Generally, in order to lower sintering temperature of sintering alumina, an oxide of alkali-earth metal, silicon or the like is added. If the amount of addition is decreased and purity of alumina is increased, insulating characteristic can further be improved, though the cost increases. High insulating characteristic can be attained at the purity of 99.6%, and higher insulating characteristic can be attained at the purity of 99.9%. Further, when the purity becomes higher, alumina also comes to have higher insulating characteristic and, at the same time, improved thermal conductivity, and with the purity of 99.5%, thermal conductivity becomes 30 W/mK. Purity of alumina may appropriately be selected in consideration of insulating characteristic, thermal conductivity and cost. Aluminum nitride is preferred as it has particularly high thermal conductivity of 170 W/mK.

Alternatively, a metal may be applied as the material for the chuck top. In that case, tungsten, molybdenum and an alloy of these having high Young's modulus may be used. Specific examples of the alloy are an alloy of tungsten and copper, and molybdenum and copper. These alloys can be produced by impregnating tungsten or molybdenum with copper. Similar to the ceramics-metal composite described above, such metal is a conductor, and therefore, by forming the chuck top conductor and forming the heater body directly applying the method described above, a chuck top for use is obtained.

In the wafer holder of the present invention, it is preferred that the chuck top deflects at most by 30 μm when a load of 3.1 MPa is applied to the chuck top. A large number of pins of the probe card for inspecting the semiconductor wafer press the semiconductor wafer on the chuck top, and therefore, the pressure also acts on the chuck top, and the chuck top deflects to no small extent. When the amount of deflection exceeds 30 μm, it becomes impossible to press the pins of the probe card uniformly onto the semiconductor wafer, and inspection of the semiconductor wafer might be failed. More preferably, the amount of deflection under pressure is at most 10 μm.

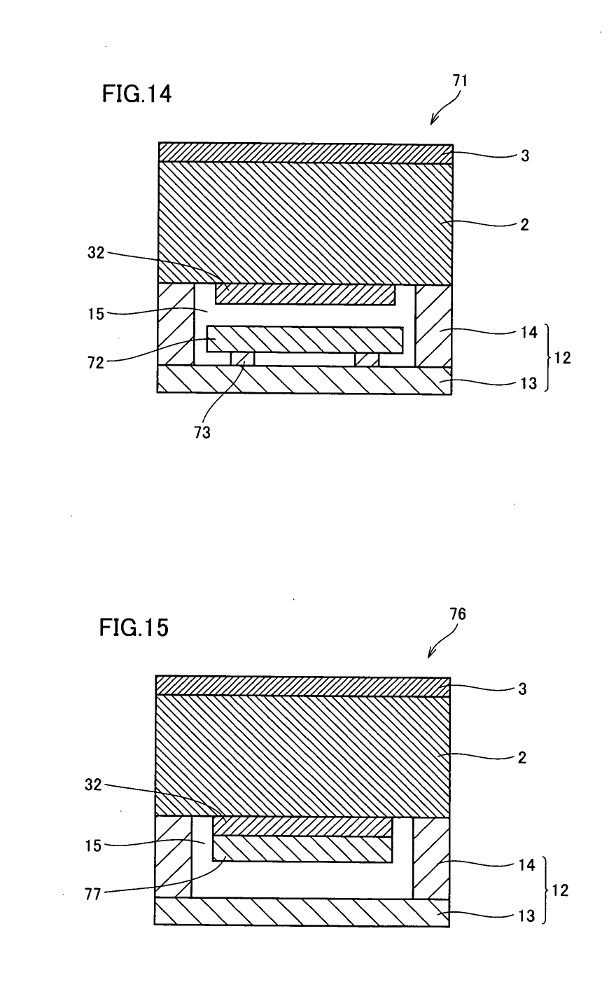

FIG. 14 is a cross-sectional view schematically showing a wafer holder 71 as a seventh preferred example of the present invention. Wafer holder 71 of the example shown in FIG. 14 has the same structure as that of wafer holder 36 of the example shown in FIG. 7 except for some points, and portions of the same structure are denoted by the same reference characters and description thereof will not be repeated. Wafer holder 71 of the example shown in FIG. 14 is characterized in that a cooling module 72 is provided in space 15 of supporter 12 having the circular tube portion 14. Provision of cooling module 72 is preferred, because, when it becomes necessary to cool chuck top 2, the heat can be removed and the chuck top 2 can be cooled rapidly, improving the throughput.

Though the material for the cooling module is not specifically limited, aluminum, copper or an alloy thereof is preferred as it has high thermal conductivity and capable of quickly removing heat from the chuck top. Use of metal material such as stainless steel, magnesium alloy, nickel or the like is also possible. To add oxidation resistance to the cooling module, an oxidation resistant metal film of nickel, gold or silver may be formed by plating or thermal spraying.

As the material for cooling module 72, ceramics may be used. Among the ceramics, aluminum nitride and silicon carbide are preferred, as they have high thermal conductivity and capable of quickly removing heat from the chuck top. Further, silicon nitride and aluminum oxynitride are preferred, as they have high mechanical strength and superior durability. Oxide ceramics such as alumina, cordierite and steatite are preferred as they are relatively inexpensive. As described above, the material for the cooling module 72 may be arbitrarily selected in consideration of intended use, cost and the like. Of these materials, nickel-plated aluminum and nickel-plated copper are particularly preferred, as they have superior oxidation resistance and high thermal conductivity, and are relatively inexpensive.

It is preferred to provide a coolant flowing in the cooling module. By the flow of coolant, the heat transferred from the chuck top to the cooling module can quickly be removed from the cooling module, and the cooling rate of the chuck top can be improved. Types of the coolant may be liquid such as water, Fluorinert or Galden, or gas such as nitrogen, air or helium. When the wafer holder of the present invention is used only at a temperature of 0° C. or higher, water is preferred considering magnitude of specific heat and cost, and when it is cooled below zero, Galden is preferred considering specific heat.

As the method of forming the passage for the coolant flow, two plates are prepared, for example, and the passage is formed by machine processing on one of the plates. In order to improve corrosion resistance and oxidation resistance, entire surfaces of the two plates are nickel-plated, and thereafter, the two plates are joined by means of screws or welding. At this time, an O-ring or the like may preferably be inserted around the passage, to prevent leakage of the coolant.

As another method of forming the flow passage, a pipe through which the coolant flows may be attached to a cooling plate. Here, in order to increase contact area between the cooling plate and the pipe, the cooling plate may be processed to have a trench of an approximately the same cross sectional shape as the pipe. and the pipe may be arranged in the trench, or the cross-sectional shape of the pipe may be made partially flat, and that portion may be fixed on the cooling plate. As to the method of fixing the metal plate and the pipe, screw fixing using a metal band, welding or brazing may be available. When deformable substance such as resin is inserted between the cooling plate and the pipe, tight contact between the two is attained and cooling efficiency can be enhanced.

At the time of heating chuck top 2, if cooling module 72 can be separated from chuck top 2, highly efficient temperature elevation becomes possible. For this purpose, preferably, cooling module 72 is made movable. FIG. 14 shows an example in which cooling module 72 is provided on elevating means 73 such as an air cylinder, realizing mobile cooling module 72. Cooling module 72 does not bear the load of probe card, and therefore, it is free from the problem of deformation caused by the load.

FIG. 15 is a cross-sectional view schematically showing a wafer holder 76 as an eighth preferred example of the present invention. Wafer holder 76 of the example shown in FIG. 15 has the same structure as that of wafer holder 36 of the example shown in FIG. 7 except for some points, and portions of the same structure are denoted by the same reference characters and description thereof will not be repeated. In the wafer holder of the present invention, when the cooling rate of the chuck top is of high importance, the cooling module may be fixed on the chuck top. FIG. 15 shows an example in which heater body 32 is provided on a side opposite to the wafer-mounting surface of chuck top 2, and a cooling module 77 is fixed on a lower surface of heater body 32.

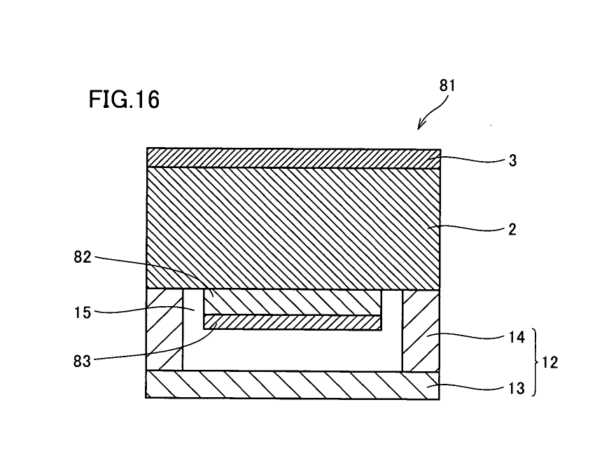

FIG. 16 is a cross-sectional view schematically showing a wafer holder 81 as a ninth preferred example of the present invention. Wafer holder 81 of the example shown in FIG. 16 has the same structure as that of wafer holder 36 of the example shown in FIG. 7 except for some points, and portions of the same structure are denoted by the same reference characters and description thereof will not be repeated. In the example shown in FIG. 16, a cooling module 82 is directly provided on a side opposite to the wafer-mounting surface of chuck top 2, and on a lower surface of cooling module 82, a heater body 83 is fixed. Here, it is also possible to insert a deformable and heat-resistant soft material having high thermal conductivity (not shown) between the side opposite to the wafer-mounting surface of chuck top 2 and cooling module 82. By providing the soft material between chuck top 2 and cooling module 82 that can moderate warp or parallelism of the two, it becomes possible to enlarge the contact area, and the original cooling performance of the cooling module can more fully be exhibited, realizing higher cooling rate.

In any of the examples described above, the method of fixing the cooling module on the wafer holder of the present invention is not specifically limited, and it can be fixed mechanically, for example, by screw fixing or clamping. When the chuck top and the cooling module and the heater body are fixed by screws, three or more screws are preferred as tight contact between each of the members can be improved, and six or more screws are more preferred.

Further, the cooling module may be provided in the space of the supporter, or the cooling module may be mounted on the supporter and the chuck top may be mounted thereon. No matter which method of mounting is adopted, cooling rate can be increased as compared with the movable example (FIG. 14), as the chuck top and the cooling module are firmly fixed. When the cooling module is mounted on the supporter, contact area between the cooling module and the chuck top increases, and therefore, the chuck top can be cooled in a shorter time.

When the cooling module fixed on the chuck top can be cooled by a coolant, it is preferred that the flow of coolant to the cooling module is stopped when the temperature of the chuck top is increased or when it is kept at a high temperature. In that case, the heat generated by the heater body is not removed by the coolant, and the heat does not escape to the outside of the system, whereby efficient temperature increase or maintenance of high temperature becomes possible. Naturally, the chuck top can be cooled efficiently by causing the coolant to flow again at the time of cooling.

Further, the chuck top itself may be formed as the cooling module, by providing a passage through which the coolant flows inside the chuck top. In that case, the time for cooling can further be reduced than when the cooling module is fixed on the chuck top. As the material for the chuck top, ceramics and metal-ceramics composite material may be used as in the foregoing. As for the structure, for example, a chuck top conductive layer is formed on one surface of a member I to be the wafer-mounting surface, and a passage for the coolant flow is formed on the opposite surface, and a member II may be integrated by brazing, glass fixing or screw fixing, on the surface having the passage formed thereon. Alternatively, a passage may be formed on one surface of member II, and the member may be integrated with member I on the surface having the passage formed thereon, or passages may be made both on members I and II, and the members may be integrated on the surfaces having the passages formed thereon. It is preferred that the difference in thermal conductivity of members I and II is as small as possible, and ideally, the members are preferably formed of the same material.

When the chuck top itself is formed as the cooling module, metal may be used as the material. Metal is advantageous as it is less expensive as compared with the ceramics or composite material of ceramics and metal and it allows easy processing so that formation of the passage is easier. However, it is susceptible to deformation under the load from the probe card, and therefore, a plate-shaped member may be provided for preventing deformation of the chuck top on the side opposite to the wafer-mounting surface of the chuck top. It is preferred that the plate for preventing deformation has Young's modulus of at least 250 GPa, as in the case where ceramics or metal-ceramics composite material is used as the material for the chuck top.

As for the position of arranging the plate for preventing deformation, it may be housed in the space formed in the supporter, or it may be inserted between the chuck top and the supporter. The chuck top and the plate for preventing deformation may be fixed by a mechanical method such as screw fixing, or may be fixed by brazing or glass fixing. Efficient heating and cooling is possible by not causing coolant to flow through the cooling module when the chuck top is heated or kept at a high temperature and causing the coolant to flow only at the time of cooling, as in the example in which the cooling module is fixed on the chuck top.

When the chuck top material is metal, the chuck top conductive layer may be newly formed on the wafer-mounting surface, if it is the case that the chuck top material is much susceptible to oxidation or alteration, or it does not have sufficiently high electric conductivity. As the method of formation, vapor deposition, sputtering, thermal spraying or plating may be used as in the foregoing.

In the structure in which the plate for preventing deformation is provided on the chuck top formed of metal, formation of the electromagnetic shield layer or the guard electrode layer similar to that described above may be possible. By way of example, on the surface opposite to the wafer-mounting surface of the chuck top, an insulated heater body is provided and covered with a metal layer, and further, the guard electrode layer is formed with an insulating layer interposed, and between the guard electrode layer and the chuck top, an insulating layer is formed. Further, the plate for preventing deformation is arranged, and the chuck top, the heater body and the plate for preventing deformation may be fixed integrally on the chuck top.

When the wafer holder of the present invention is applied, for example, to a wafer prober, a handler apparatus or a tester apparatus, even a semiconductor having minute circuitry can be inspected without any contact failure.

Among the wafer holders in accordance with the present invention described above, those having a heater body may be suitably used as the heater unit for a wafer prober. The present invention also provides such a heater unit for the wafer prober. Further, the present invention also provides the wafer prober on which the heater unit for the wafer prober described above is mounted. In the wafer prober of the present invention, any conventionally known structure may be adopted for the structures other than the heater unit of the present invention described above, without any specific limitation.

### EXAMPLES

### Example 1

Ten wafer holders in accordance with the present invention and one wafer holder as a comparative example as listed in Table 1 were fabricated. These wafer holders were each mounted on a wafer prober, and semiconductors were inspected under seven different inspection conditions as shown in Table 2. Respective wafer holders will be described in the following.

Wafer holder 31 as the example shown in FIG. 6 was fabricated. As chuck top 2, an Si—SiC substrate having the diameter of 310 mm and thickness of 15 mm was prepared. On one surface of the substrate, a trench in a concentrical circle for vacuum-chucking a wafer and a through hole were formed, and nickel plating was applied as the chuck top conductive layer, whereby the wafer-mounting surface was prepared. Thereafter, the wafer-mounting surface was polished and finished to have the overall warp of 10 μm and surface roughness Ra of 0.02 μm, and chuck top 2 was completed.

Thereafter, as supporter 33, an Al—SiC plate having the diameter of 310 mm and the thickness of 40 mm was prepared. Al—SiC had Young's modulus of 190 GPa and thermal conductivity of 180 W/mK. This material will be denoted as Al—SiC (1). The surface to be in contact with the chuck top and the bottom surface of supporter 33 were finished to have the flatness of 0.09 mm, and thereafter, the surface on the chuck top side was counter-bored to have the inner diameter of 290 mm and the depth of 3 mm, to form a space 34 for arranging heater body 32.

On chuck top 2, stainless steel foil insulted with mica was attached as the electromagnetic shield layer (not shown), and further, heater body 32 sandwiched between mica was attached. As heater body 32, stainless steel foil was etched to a prescribed pattern. The electromagnetic shield layer and heater body 32 were arranged at positions to be housed in the space provided in the supporter. Further, in supporter 33, a through hole was formed for connecting an electrode for feeding power to heater body 32, as shown in FIG. 9. On the side surface and bottom surface of supporter 33, aluminum was thermally sprayed, to form the metal layer.

Thereafter, on supporter 33, chuck top 2 having heater body 32 and the electromagnetic shield layer attached thereon was mounted, thus forming wafer holder 31 for a wafer prober.

Wafer holder 31 was mounted on a wafer prober, and semiconductors were inspected continuously for 10 hours, under seven different inspection conditions shown in Table 2.

### Comparative Example

A wafer holder was fabricated in the similar manner as in Example 1 except that the surface to be in contact with the chuck top and the bottom surface of the supporter were finished to the flatness of 0.12 mm, and mounted on a wafer prober, and semiconductors were inspected continuously for 10 hours, under seven different inspection conditions shown in Table 2.

### Example 2

A wafer holder was fabricated in the similar manner as in Example 1 except that the surface to be in contact with the chuck top and the bottom surface of the supporter were finished to the flatness of 0.05 mm, and mounted on a wafer prober, and semiconductors were inspected continuously for 10 hours, under seven different inspection conditions shown in Table 2.

### Example 3

A wafer holder was fabricated in the similar manner as in Example 1 except that the surface to be in contact with the chuck top and the bottom surface of the supporter were finished to the flatness of 0.009 mm, and mounted on a wafer prober, and semiconductors were inspected continuously for 10 hours, under seven different inspection conditions shown in Table 2.

### Example 4

A wafer holder was fabricated in the similar manner as in Example 3 except that the material of the supporter was Al—SiC having Young's modulus of 210 GPa and thermal conductivity of 170 W/mK. This material will be denoted as Al—SiC (2). The wafer holder was mounted on a wafer prober, and semiconductors were inspected continuously for 10 hours, under seven different inspection conditions shown in Table 2.

### Example 5

Wafer holder 36 having the structure shown in FIG. 7 was fabricated in the similar manner as in Example 4 except that supporter 12 having a circular tube portion 14 was used and heater body 32 and the electromagnetic shield layer (not shown) within space 15 of supporter 12 were attached to chuck top 2. The obtained wafer holder 36 was mounted on a wafer prober, and semiconductors were inspected continuously for 10 hours, under seven different inspection conditions shown in Table 2.

### Example 6

A wafer holder was fabricated in the similar manner as in Example 4 except that 16 pillars 23 were used as shown in FIG. 5 as supporter 22, and the heater body and the electromagnetic shield layer within the space of supporter were attached to the chuck top. The obtained wafer holder was mounted on a wafer prober, and semiconductors were inspected continuously for 10 hours, under seven different inspection conditions shown in Table 2.

### Example 7

A wafer holder was fabricated in the similar manner as in Example 5 except that stainless steel was used as the material for the supporter, and mounted on a wafer prober, and semiconductors were inspected continuously for 10 hours, under seven different inspection conditions shown in Table 2.

### Example 8

A wafer holder was fabricated in the similar manner as in Example 5 except that alumina composite material was used as the material for the supporter, and mounted on a wafer prober, and semiconductors were inspected continuously for 10 hours, under seven different inspection conditions shown in Table 2.

### Example 9

A wafer holder was fabricated in the similar manner as in Example 5 except that mullite-alumina composite material was used as the material for the supporter, and mounted on a wafer prober, and semiconductors were inspected continuously for 10 hours, under seven different inspection conditions shown in Table 2.

### Example 10

A wafer holder was fabricated in the similar manner as in Example 5 except that mullite was used as the material for the supporter, and mounted on a wafer prober, and semiconductors were inspected continuously for 10 hours, under seven different inspection conditions shown in Table 2.

TABLE 1

| | Supporter shape and physical properties | | | | |
|---|---|---|---|---|---|
| | | | Young's | | Thermal |
| | Flatness | | modulus | | conductivity |
| No. | (mm) | Material | (Gpa) | Shape | (W/mK) |
| Comparative | 0.12 | Al—SiC(1) | 190 | cylinder | 180 |
| Example | | | | | |
| Example 1 | 0.09 | Al—SiC(1) | 190 | cylinder | 180 |
| Example 2 | 0.05 | Al—SiC(1) | 190 | cylinder | 180 |
| Example 3 | 0.009 | Al—SiC(1) | 190 | cylinder | 180 |
| Example 4 | 0.009 | Al—SiC(2) | 210 | cylinder | 170 |
| Example 5 | 0.009 | Al—SiC(2) | 210 | circular tube | 170 |
| Example 6 | 0.009 | Al—SiC(2) | 210 | pillars | 170 |
| | | | | (16 in concentric | |
| | | | | arrangement) | |
| Example 7 | 0.009 | stainless steel | 210 | circular tube | 16 |
| Example 8 | 0.009 | alumina | 380 | circular tube | 32 |
| Example 9 | 0.009 | mullite-alumina | 250 | circular tube | 4 |
| | | composite material | | | |
| Example 10 | 0.009 | mullite | 210 | circular tube | 1.7 |

As described above, using wafer probers mounting 10 wafer holders in accordance with the present invention and one in accordance with the comparative example, semiconductors were inspected continuously for 10 hours, under seven different inspection conditions shown in Table 2, and occurrence of contact failure at the time of inspection was as shown in Table 2.

TABLE 2

| | Occurrence of contact failure during inspection | | | | | | |
|---|---|---|---|---|---|---|---|
| | (A: not failed, B: failed) | | | | | | |
| Probe card load (kgf) | 100 | 150 | 200 | 250 | 250 | 250 | 250 |
| Inspection | 20 | 20 | 20 | 20 | 100 | 150 | 200 |
| temperature (° C.) | | | | | | | |
| Comparative Example | B | B | B | B | B | B | B |
| Example 1 | A | B | B | B | B | B | B |
| Example 2 | A | A | B | B | B | B | B |
| Example 3 | A | A | A | B | B | B | B |
| Example 4 | A | A | A | A | B | B | B |
| Example 5 | A | A | A | A | A | B | B |
| Example 6 | A | A | A | A | A | B | B |
| Example 7 | A | A | A | A | A | A | B |
| Example 8 | A | A | A | A | A | A | A |
| Example 9 | A | A | A | A | A | A | A |
| Example 10 | A | A | A | A | A | A | A |

According to the present invention, in a wafer holder having a chuck top for mounting and fixing a wafer and a supporter supporting the chuck top, by setting flatness of said supporter to be at most 0.1 mm, a wafer holder hardly deformable even under high load and capable of effectively preventing contact failure can be provided.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A wafer holder, comprising:
a chuck top for mounting a semiconductor wafer; and
a supporter supporting the chuck top, and having flatness of at most 0.1 mm.

2. The wafer holder according to claim 1, wherein
flatness of said supporter is at most 0.05 mm.

3. The wafer holder according to claim 1, wherein
flatness of said supporter is at most 0.01 mm.

4. The wafer holder according to claim 1, wherein
Young's modulus of said supporter is at least 200 GPa.

5. The wafer holder according to claim 1, wherein
said supporter includes a circular tube portion.

6. The wafer holder according to claim 1, wherein
said supporter includes a plurality of pillars.

7. The wafer holder according to claim 1, wherein
thermal conductivity of said supporter is at most 40 W/mK.

8. The wafer holder according to claim 1, wherein
main component of a material forming said supporter is any of mullite, alumina and a mullite-alumina composite.

9. A heater unit for a wafer prober comprising the wafer holder in accordance with claim 1.

10. A wafer prober comprising the heater unit in accordance with claim 9.
